(19) United States
(12) Patent Application Publication
(10) Pub. No.: US 2012/0002367 A1
(43) Pub. Date: Jan. 5, 2012

(54) UNIVERSAL CONNECTION HUB WITH PERIPHERAL ORGANIZING BAYS

(76) Inventor: Gregg DeFronzo, Sherman Oaks, CA (US)

(21) Appl. No.: 13/056,596

(22) PCT Filed: Jul. 28, 2009
(86) PCT No.: PCT/US09/04352

§ 371 Date: Sep. 23, 2011

Related U.S. Application Data
(60) Provisional application No. 61/137,273, filed on Jul. 28, 2008.

(51) Int. Cl. G06F 1/16; H02J 7/00; H05K 5/00

(52) U.S. Cl. 361/679.41; 361/807; 320/137

(57) ABSTRACT

The present inventor devised, among other things, a universal connection hub with one or more peripheral storage bays. One exemplary connection hub includes one or more connection hubs within a rectangular housing. The housing has a generally vertical exterior sidewall with two bays for receiving and storing corresponding peripheral modules, such as a rechargeable battery and a portable hard drive. The peripheral modules include connectors which connect to corresponding connectors of one of the internal connection hubs. The connection hub is itself connected to a USB or Firewire port connector mounted in the exterior sidewall for connection to a laptop or notebook computer. Flat top and bottom panels are mounted to the vertical sidewall. When sized appropriately, the housing supports a laptop or notebook computer, giving the appearance of a docking station. The peripheral storage bays, which can receive various types of devices, such as smart phones, music players, hard drives, batteries, television tuners, and so forth, ultimately reduce the clutter on user work surfaces.

### RELATED APPLICATIONS

The present application claims priority to U.S. Provisional Patent Application 61/137,273 which was filed on Jul. 28, 2008 and which is incorporated herein by reference.

### COPYRIGHT NOTICE AND PERMISSION

A portion of this patent document contains material subject to copyright protection. The copyright owner has no objection to the facsimile reproduction by anyone of the patent document or the patent disclosure, as it appears in the Patent and Trademark Office patent files or records, but otherwise reserves all copyrights whatsoever. The following notice applies to this document: Copyright© 2008, 2009 GREGG DeFRONZO.

### TECHNICAL FIELD

Various embodiments of the present invention concern connection hubs for computers, particularly laptops and notebook computers.

### BACKGROUND

Laptops and notebook computers are well-known portable computing devices. These and other computers are typically equipped with a fixed number of external input-output ports, such as Universal Serial Bus (USB) or Firewire (FW) ports, that allow users to connect the computers to peripheral devices, such as printers, disk drives, pointing devices, and loud speakers, to name a few. (USB and FW refer to particular standardized communication and connector protocols that computers and peripherals device can use to connect and communicate with each other.)

Sometimes, the number of peripherals that users want to connect exceeds the number of ports that are available on their computers. In such cases, users can purchase a connection hub, such as a USB or Firewire hub, that which effectively converts one port into many ports. For example, some USB hubs convert a single USB port into as many as five ports, enabling the user to connect five peripherals instead of one to the one port on the computer.

The present inventor recognized one or more problems with conventional connections hubs. For example, conventional hubs leave the user to manage and work around a tangle web of cables. Even when the cords are well managed, the hubs themselves not only take up valuable surface area on a user desks, but also clash aesthetically with the computers they are connected to. Moreover, the peripherals themselves take up surface area and add to desktop clutter.

Accordingly, the present inventor identified a need for better connection hubs.

### SUMMARY

To address this and/or other needs, the present inventor devised, among other things, a universal connection hub with peripheral storage bays. In the exemplary embodiment, the connection hub includes a rectangular housing having a generally vertical exterior sidewall with two bays for receiving and storing corresponding peripheral modules, for example a rechargeable battery and a 2.5-inch portable hard drive. (In some embodiments, the battery powers the hard drive.) The peripheral modules include male or female USB or Firewire connectors which connect to corresponding female or male USB or Firewire connectors on a connection hub within the housing. The connection hub is itself connected to a USB or Firewire port connector mounted in the exterior sidewall for connection to a laptop or notebook computer. Additionally, substantially planar top and bottom panels are mounted to the vertical sidewall.

In some embodiments, the footprint of the universal connection hub is approximately the same as that of the laptop or notebook computer, enabling the user to stack the computer on the top surface of the hub. In this instance, the hub may be regarded as a docking station. Moreover, in some variants, the top surface as well as the remainder of the hub housing is formed of cast or machined aluminum, and thus functions as a heat sink for computer as well as the peripheral modules within the connection hub.

### BRIEF DESCRIPTION OF THE DRAWINGS

FIG. 1 is a block diagram of an exemplary universal connection hub with peripheral storage bays, corresponding to one or more embodiments of the present invention.

FIG. 2A is a front perspective view of an exemplary computer system incorporating an exemplary universal connection hub (or docking station), and thus corresponding to one or more embodiments of the present invention.

FIG. 2B is a rear perspective view of the exemplary computer system in FIG. 2A, corresponding to one or more embodiments of the present invention.

FIG. 2C is a perspective view of the exemplary universal connection hub in FIG. 2A, corresponding to one or more embodiments of the present invention.

FIG. 2D is a left side view of the exemplary universal connection hub in FIG. 2A, corresponding to one or more embodiments of the present invention.

FIG. 2E is a right side view of the exemplary universal connection hub in FIG. 2A, corresponding to one or more embodiments of the present invention.

FIG. 2F is a front side view of the exemplary universal connection hub in FIG. 2A, corresponding to one or more embodiments of the present invention.

FIG. 2G is a back side view the exemplary universal connection hub in FIG. 2A, corresponding to one or more embodiments of the present invention.

FIG. 2H is a perspective view of a partial assembly of the exemplary connection hub in FIG. 2A, corresponding to one or more embodiments of the present invention.

FIG. 2I is a perspective view of a lower housing assembly of the exemplary connection hub in FIG. 2A, corresponding to one or more embodiments of the present invention.

FIG. 2J is a partial perspective view of a housing portion of a peripheral module compatible with the exemplary connection hub and corresponding to one or more embodiments of the present invention.

FIG. 2K is a perspective view of a peripheral module which serves as a docking station for a portable music player and/or smart phone.

FIG. 3 is block schematic diagram of the exemplary connection hub (or docking station) corresponding to one or more embodiments of the present invention.

### DETAILED DESCRIPTION

This description, which incorporates the drawings and the appended claims, describes one or more specific embodiments of an invention. These embodiments, offered not to limit but only to exemplify and teach the invention, are shown and described in sufficient detail to enable those skilled in the art to implement or practice the invention. Thus, where appropriate to avoid obscuring the invention, the description may omit certain information known to those of skill in the art.

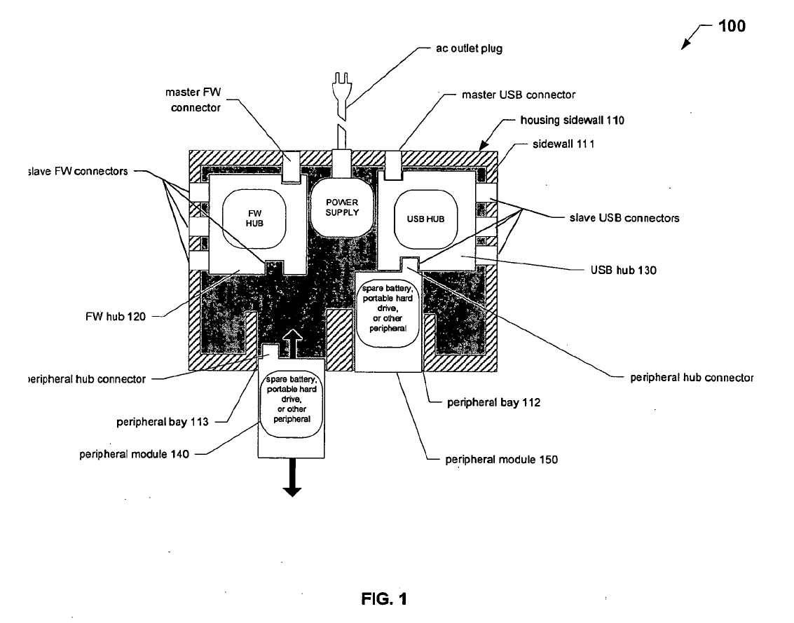

FIG. 1 shows an exemplary universal connection hub 100. Universal connection hub, which in some embodiments may appear and/or serve as a laptop docking station, includes an aluminum housing 110, a firewire hub 120, a USB hub 130, a peripheral module 140, and a peripheral module 150.

Housing 110 includes a vertical sidewall 111. Sidewall 111 encircles firewire (FW) hub 120 and USB hub 130. Firewire hub 120 includes a master FW connector which is for connection to a FW port of computing device, such as a laptop or notebook computer. Hub 120 also includes slave FW ports and associated connectors mounted in sidewall 111, and at least one internal FW port connector, that is inside housing 110 for connection to peripheral module 140. Similarly, USB hub 130 includes a master USB connector for connection to a USB port of a computing device, and slave USB ports, at least one of which is inside of housing 110 for connection to peripheral module 150.

Peripheral modules 140 and 150 are slideably insertable and removable from respective peripheral bays 113 and 112. The modules include male or female connectors that connect to one or more of the ports of the hubs 120 and 130. In some embodiments, one or more of modules 130 and 140 includes a rechargeable batter. In some embodiments, the modules include data storage devices. In some embodiments, the modules include portable music player, television tuners, smart telephones, credit card readers, etc. The modules allow users to expand the functionality of computing device as may be desired, while the peripheral bays provide efficient and aesthetically pleasing storage.

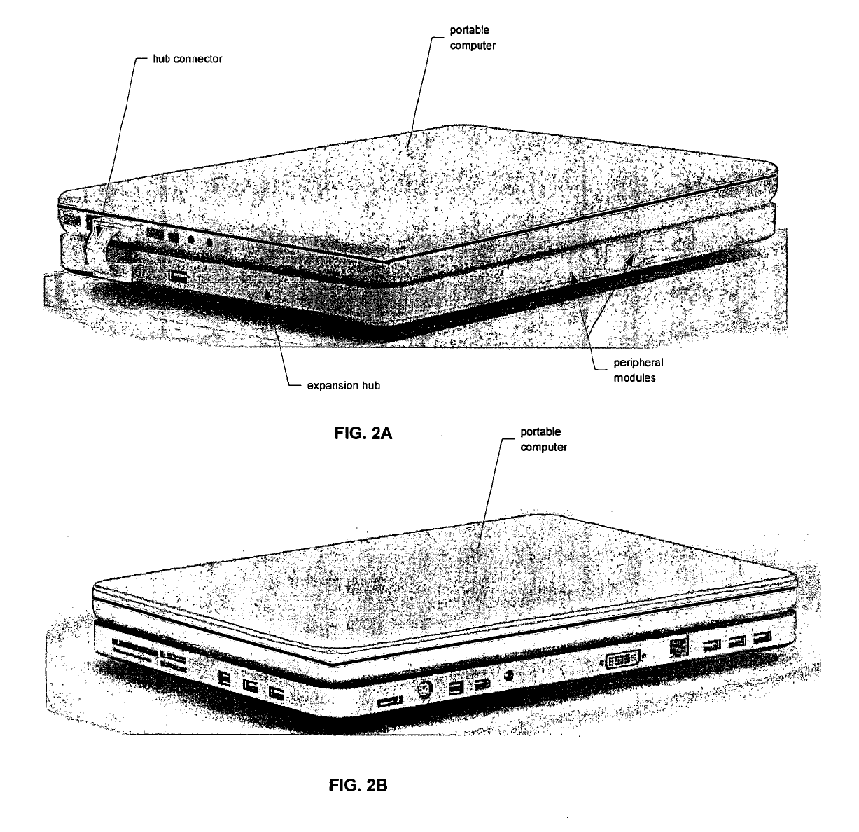

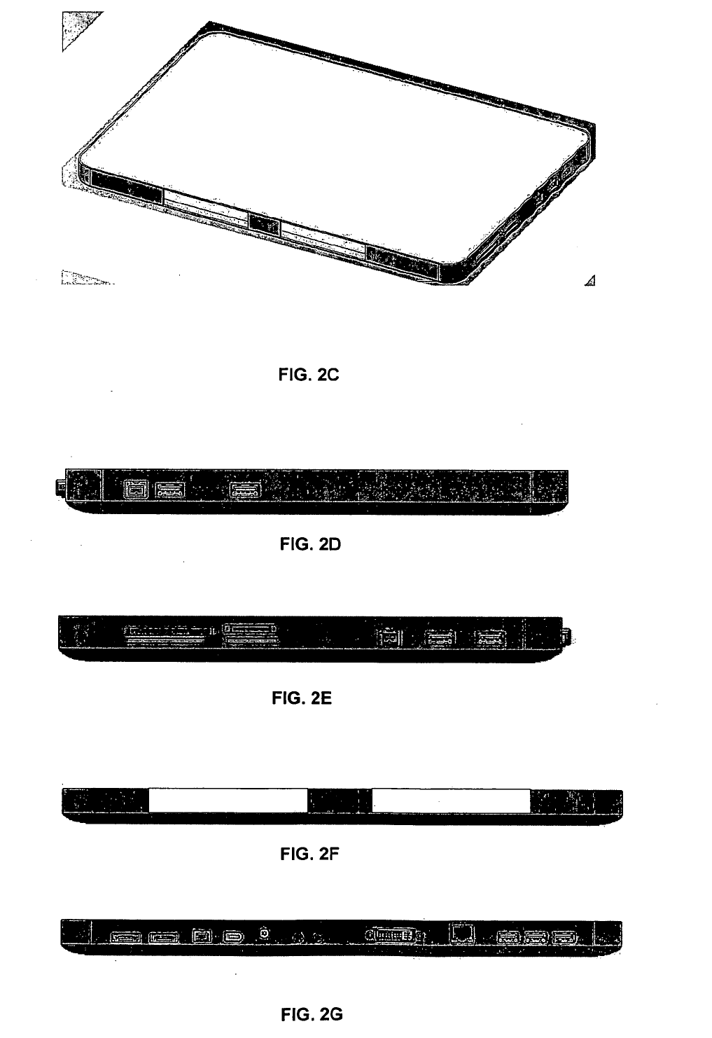

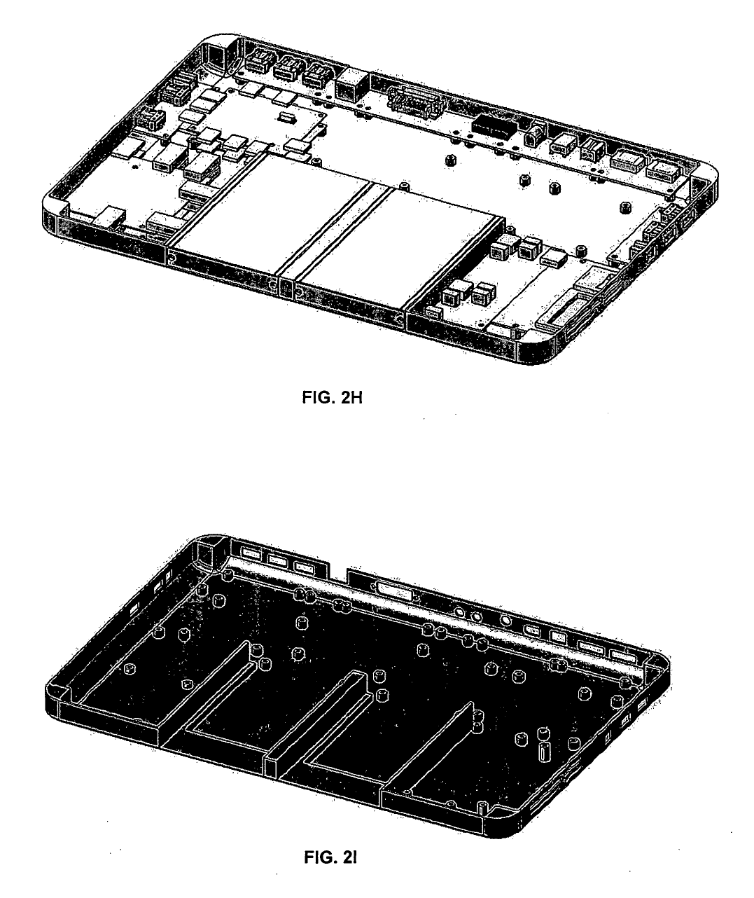

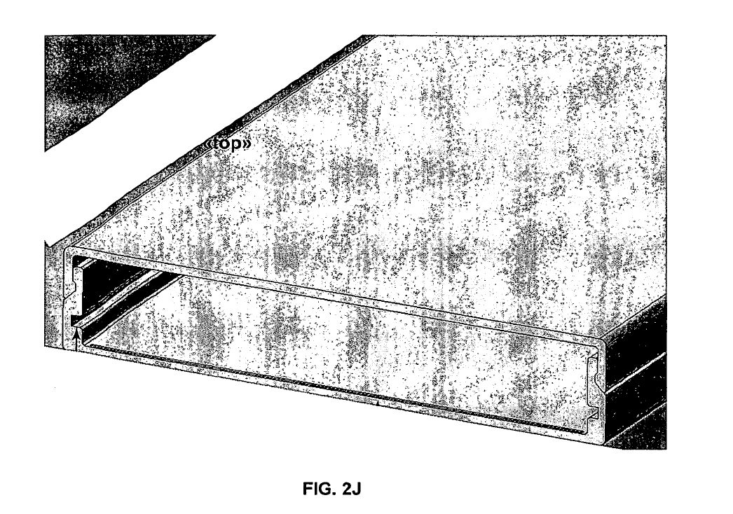

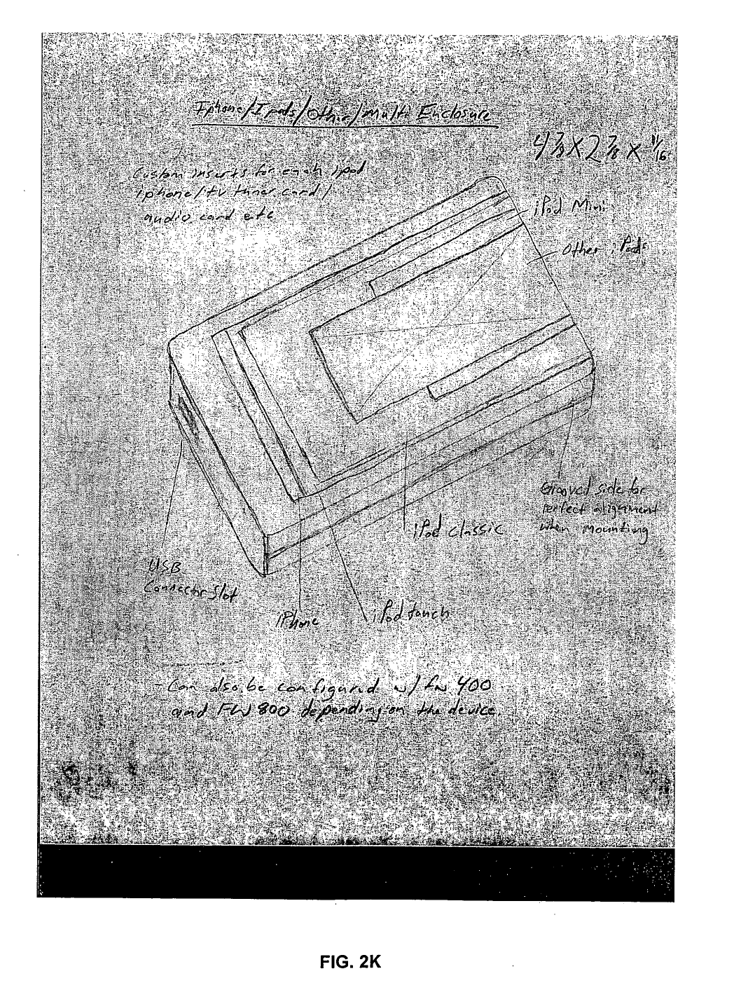

FIGS. 2A and 2B show respective front and rear perspective views of an exemplary computer system 200. System 200 includes a universal expansion hub 210, which like hub 100, includes peripheral storage bays 212 and corresponding peripheral modules 212. System 200 also shows that system 200 includes a laptop computer 220 resting on a top surface of hub 210. A connector 230, for example USB or Firewire or other conventional or proprietary type, connects a port of computer 220 to a port in the sidewall of hub 210.

FIGS. 2C-2G show various views of hub 210. Respectively, the various views are a perspective view, a left side view, a right side view, a front view, and a back view. Notably, these views illustrate what many might consider a pleasing aesthetic in the design of the hub 210. As shown in relation to the size of laptop computer 220 in FIGS. 2A and 2B, hub 210 has a footprint approximately the same as that of computer 220, giving it the appearance of a low-profile docking station.

FIG. 2H shows a partial assembly of hub 210, specifically, a lower housing assembly 214. Assembly 214 includes peripheral bays 215 and 216, which contain peripheral modules 212.

FIG. 2I shows lower housing assembly 214 without the peripheral modules. In some embodiments, the peripheral bays include bay walls that include side rails or grooves in some embodiments (not visible in this view) to engage slideably with side rails or ribs on confronting walls of the peripheral modules. In some embodiments, the bays include drawers and a USB or other type of female connector in the back or sidewall of each drawer to connect with a peripheral device, such as flash drive or portable music player, that can fit in the drawer. Foam or other conformal devices may be used in the drawer to provide a secure fit for the peripheral. In some embodiments, more than one peripheral may be stored and connected in the drawer, for example, two or more flash drives. FIG. 2J also shows that the peripheral modules may be constructed using two halves that snap together. The lower half sidewalls include a grooves for receiving a printed circuit board which includes the circuitry for achieving the desired peripheral functionality, such as a data storage.

In the exemplary embodiment, all of the housing of the universal hub is formed of cast or machined aluminum. Aluminum conducts heat well, allowing the housing or portions thereof to serve as a heat sink. Other embodiments may use other materials.

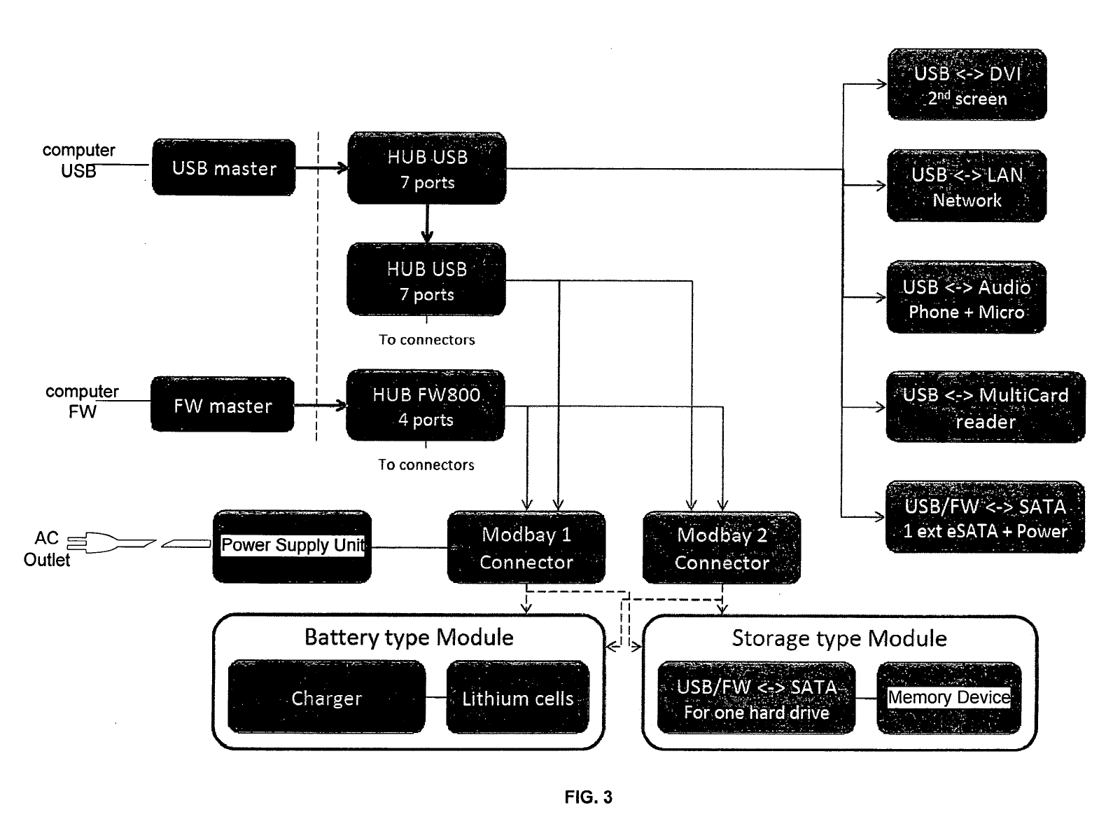

FIG. 3 shows block schematic diagram of the exemplary connection hub (or docking station) 200. A power supply unit received power via an AC outlet or via the battery type module. If AC power is available and a battery type peripheral module or a peripheral device having a rechargeable battery, the power supply unit recharges the battery in the peripheral device. If AC power is not available, the battery type peripheral module supplies power to the power supply unit, enabling the connection hub to operate. In some embodiments, the power supply unit also charges the battery of a laptop or notebook computer. The battery type peripheral module may serve as spare battery for the computer.

These and other embodiments as shown and described may include one or more of the following features or functionality:

Integrated 2.5″ form factor portable hard drives (in some peripheral modules)

Wireless input-output ports, such as Bluetooth compatible ports.
Smooth flattop surface that omits connections, allowing it to be universally compatible (that is, with laptops or notebooks from at least two different computer makers. A user simply places their portable or even desktop computer or computer monitor on top of the low profile docking station.

### CONCLUSION

The embodiments described above are intended only to illustrate and teach one or more ways of practicing or implementing the present invention, not to restrict its breadth or scope. The actual scope of the invention, which embraces all ways of practicing or implementing the teachings of the invention, is defined only by the issued claims and their equivalents.

1. A connection apparatus for computing devices, the apparatus comprising:
a housing having a sidewall;
at least one USB or Firewire connector mounted in the sidewall of the housing;
a connection hub electrically coupled to the one connector and located within the housing, the connection hub having at least one other connector;
first and second peripheral bays providing access to an interior region of housing;
a first peripheral module positioned within the first peripheral bay and having a first connector electrically coupled to the connection hub.
a second peripheral module positioned within the second peripheral bay and having a second connector electrically coupled to the connection hub.

2. The connection apparatus of claim 1, wherein the first peripheral module includes a rechargeable battery, and the second peripheral module includes a data storage device.

3. The connection apparatus of claim 2, wherein the rechargeable battery is coupled to power the connection hub and the data storage device.

4. A connection apparatus for computing devices, the apparatus comprising:
Housing means for defining an interior;
hub means, within the interior, for replicating a port connection on a computing device;
first and second means for a peripheral device within the interior;
a first peripheral module positioned within the first peripheral bay and having a first connector electrically coupled to the connection hub.
a second peripheral module positioned within the second peripheral bay and having a second connector electrically coupled to the connection hub.

5. The connection apparatus of claim 4, wherein the first peripheral module includes a rechargeable battery, and the second peripheral module includes a data storage device.

6. The connection apparatus of claim 5, wherein the rechargeable battery is coupled to power the connection hub and the data storage device.

7. A docking station for coupling to a laptop computer having a plurality of i/o ports and a battery, the docking station comprising:
a power cord for coupling to an AC power outlet
means for coupling to and expanding one or more of the i/o ports of the laptop computer;
a first battery bay for receiving and charging a first battery compatible with the laptop computer, with first battery bay coupled to a regulated DC power supply coupled to the power cord;
a first hard drive bay for receiving a first portable hard drive module, the first hard drive bay having at least one i/o port for coupling to an i/o port of the laptop computer via the means for coupling; and
an enclosure for enclosing the first battery bay and the first hard drive bay, the enclosure having a top major surface for supporting the laptop computer and having a front face extending upward above the top major surface to hide the seam between a lower surface of the laptop computer and the top major surface of the docking station when the laptop computer is docked at the docking station.

8. The docking station of claim 7, further including a bay for receiving, syncing, and charging a mobile telephone, such as the iPhone.

9. The docking station of claim 7, further comprising a built-in or integrated surge protector coupled between the power cord and the regulated DC power supply.

10. The docking station of claim 7, further including a second battery bay for receiving and charging a second battery compatible with the laptop computer.

11. The docking station of claim 7, further including a second hard drive bay for receiving a second portable harddrive module, the second hard drive module having at least one i/o port for coupling to an i/o port of the laptop computer via the means for coupling.

12. The docking station of claim 7, further including means for coupling to a computer display; means for coupling to a printer; and means for coupling to an interne connection.

13. A docking station for coupling to a laptop computer having a plurality of i/o ports and a battery, the docking station comprising:
a power cord for coupling to an AC power outlet;
means for coupling to one or more computer displays;
a first battery bay for receiving and charging a first battery compatible with the laptop computer, with first battery bay coupled to a regulated DC power supply coupled to the power cord.

14. The docking station of claim 13, further including an enclosure for enclosing the first battery bay, the enclosure having a top major surface for supporting the laptop computer and having a front face extending upward above the top major surface to hide the seam between a lower surface of the laptop computer and the top major surface of the docking station when the laptop computer is docked at the docking station.

15. A method of operating a docking station, the method comprising:
coupling the docking station to an AC power source;
loading a spare battery for the laptop computer into the docking station; and
charging the spare battery via power derived from the AC power source.

16. The method of claim 15, further comprising:
coupling a mobile telephone or music player to the docking station; and
charging the mobile telephone or music player via power derived from the AC power source.

17. The method of claim 15, wherein the docking station has a bay for receiving a peripheral device, the method comprising:
installing a first hard drive module in the bay and storing data from a laptop computer on the first hard drive; and
removing the first hard drive module from the bay and installing another type of peripheral device into the bay.
